(19) United States
(12) Patent Application Publication
(10) Pub. No.: US 2019/0027559 A1
(43) Pub. Date: Jan. 24, 2019

(54) METHODS AND SYSTEMS FOR CHEMICALLY ENCODING HIGH-RESOLUTION SHAPES IN SILICON NANOWIRES

(71) Applicant: The University of North Carolina at Chapel Hill, Chapel Hill, NC (US)

(72) Inventors: James F. Cahoon, Chapel Hill, NC (US); Joseph D. Christesen, Carrboro, NC (US); Christopher W. Pinion, Chapel Hill, NC (US)

(21) Appl. No.: 16/129,394

(22) Filed: Sep. 12, 2018

Related U.S. Application Data
(62) Division of application No. 14/925,530, filed on Oct. 28, 2015.
Application No. 14/925,530 is a continuation of application No. PCT/US2014/035920, filed on Apr. 29, 2014.
(60) Provisional application No. 61/817,098, filed on Apr. 29, 2013.

(51) Int. Cl. H01L 29/06; G01Q 60/38; B81B 3/00; B81C 1/00; H01L 21/02; H01L 21/283; H01L 29/16; H01L 31/09; H01L 31/0352; H01L 21/306; H01L 31/028

(52) U.S. Cl. CPC H01L 29/0673; Y02E 10/50; H01L 31/028; B81B 3/0021; B81B 2203/0118; B81B 2203/0361; B81C 1/00111; B81C 1/0015; B81C 2201/013; B81C 2201/0171; B81C 2201/0176; H01L 21/02238; H01L 21/02255; H01L 21/02532; H01L 21/02576; H01L 21/02579; H01L 21/02603; H01L 21/0262; H01L 21/283; H01L 29/16; H01L 31/09; H01L 31/035281; H01L 31/03529; H01L 21/30604; G01Q 60/38

(57) ABSTRACT

Methods of chemically encoding high-resolution shapes in silicon nanowires during metal nanoparticle catalyzed vapor-liquid-solid growth or vapor-solid-solid growth are provided. In situ phosphorus or boron doping of the silicon nanowires can be controlled during the growth of the silicon nanowires such that high-resolution shapes can be etched along a growth axis on the silicon nanowires. Nanowires with an encoded morphology can have high-resolution shapes with a size resolution of about 1,000 nm to about 10 nm and comprise geometrical shapes, conical profiles, nanogaps and gratings.

### CROSS REFERENCE TO RELATED APPLICATIONS

This application is a divisional of and claims priority to Ser. No. 14/925,530 filed Oct. 28, 2015, which is a continuation of and claims priority to PCT/US2014/035920 filed Apr. 29, 2014 which claims the benefit of and priority to U.S. Provisional Application No. 61/817,098, filed Apr. 29, 2013, the entire disclosures of which are incorporated by reference herein.

### TECHNICAL FIELD

The presently disclosed subject matter relates to methods and systems for chemically encoding high-resolution shapes in silicon nanowires. The presently disclosed subject matter also relates to the use of such nanowires for nanophotonic and plasmonic structures or as a template to create nanostructures in other materials.

### BACKGROUND

Most semiconductor technologies rely on the ability to pattern materials with nanometer-scale features using top-down lithographic tools. Semiconductor nanowires (NWs) are recognized as an especially important technological building block because the high aspect ratio can be used for longitudinal transport of electrical or optical signals. A variety of devices have been demonstrated, including sensors, waveguides, phase-change memory, light-emitting diodes, and solar cells. Nevertheless, current NW-based technology has been limited by the material's translational symmetry and the inability to pattern arbitrary, nanometer-scale morphological features.

A method for accurate, nanometer-scale control of morphology in single-crystalline semiconductor NWs has not been developed. Thus, a need remains for methods of chemically encoding high-resolution shapes in NWs, such as silicon (Si) NWs. A need also remains for Si NWs with high-resolution morphological features that can be utilized in nanophotonic, plasmonic and electronic applications.

### SUMMARY

The presently disclosed subject matter provides methods and systems for chemically encoding high-resolution shapes in silicon nanowires. The presently disclosed subject matter also relates to the use of such nanowires for nanophotonic and plasmonic structures or as a template to create nanostructures in other materials.

An object of the presently disclosed subject matter having been stated hereinabove, and which is achieved in whole or in part by the presently disclosed subject matter, other objects will become evident as the description proceeds when taken in connection with the accompanying Examples as best described hereinbelow.

### BRIEF DESCRIPTION OF THE DRAWINGS

The presently disclosed subject matter can be better understood by referring to the following figures. The components in the figures are not necessarily to scale, emphasis instead being placed upon illustrating the principles of the presently disclosed subject matter (often schematically). In the figures, like reference numerals designate corresponding parts throughout the different views. A further understanding of the presently disclosed subject matter can be obtained by reference to an embodiment set forth in the illustrations of the accompanying drawings. Although the illustrated embodiment is merely exemplary of systems for carrying out the presently disclosed subject matter, both the organization and method of operation of the presently disclosed subject matter, in general, together with further objectives and advantages thereof, may be more easily understood by reference to the drawings and the following description. The drawings are not intended to limit the scope of this presently disclosed subject matter, which is set forth with particularity in the claims as appended or as subsequently amended, but merely to clarify and exemplify the presently disclosed subject matter.

For a more complete understanding of the presently disclosed subject matter, reference is now made to the following drawings in which:

FIGS. 1A-1C depict the synthesis of Si NWs with encoded morphology. FIG. 1A is a flow-chart and corresponding schematic depiction of the sequential process for synthesis of NW morphologies as disclosed herein. FIG. 1B is a schematic illustration of NW growth including rapid modulation of P dopant incorporation to form heavily-doped n-type (n) and undoped intrinsic (i) segments that are selectively etched using wet-chemical methods to form a grating. FIG. 1C is a scanning electron microscope (SEM) image of a NW grating encoded (from left to right) with sequential intrinsic segments for 200, 100, 50, 25, 10, and 5 seconds (scale bar, 500 nm);

FIGS. 2A-2D are SEM images and graphical depictions characterizing NW growth, etching, and morphology. FIG. 2A is an SEM image of a grating-encoded NW more than 50 μm in axial length (scale bar, 5 μm), with select sections of the NW shown in higher magnification for illustrative purposes (scale bars, 200 nm). FIG. 2B is a graph plotting the radial etch rate of Si NWs as a function of encoded P doping levels (curved line represents the best fit to a single exponential function), with an inset SEM image of a NW with segments I, II, and III encoded with P doping levels of 1×10²⁰ cm⁻³, 5×10¹⁹ cm⁻³, and intrinsic, respectively, and etched for 25 seconds (scale bar, 200 nm). FIG. 2C is an SEM image of a NW encoded with a bow-tie morphology (scale bar, 100 nm). FIG. 2D is a graph plotting NW diameter (heavy line and left-hand axis) as a function of length for the bow-tie shown in FIG. 2C, and measured phosphine flow rate (light line and right-hand axis) in standard cubic centimeters per minute (sccm) as a function of time during CVD growth;

FIGS. 3A-3J, and corresponding FIGS. 3A′-3J′, depict a series of phosphine flow profiles (FIGS. 3A-3J) for the synthesis of Si NWs with complex morphology, and SEM images (FIGS. 3A′-3J′) of the Si NWs synthesized using each phosphine flow profile (all scale bars, 200 nm; flow rates vary from 0 to 20 sccm for each NW);

FIGS. 4A-4H are schematic depictions of the synthesis of nanogap-encoded NWs for plasmonics, and analytical data pertaining thereto. FIG. 4A is a schematic illustration and flow chart of a process of gold (Au) deposition on a nanogap-encoded NW. FIGS. 4B and 4C are SEM images of nanogap-encoded Si NWs with 50 nm Au, gaps of about 30 nm, and segment lengths of about 775 nm (FIG. 4B) and about 1175 nm (FIG. 4C) (scale bars, 200 nm). FIGS. 4D and 4E are finite-element optical simulations of the Si/Au nanogap structures depicted in FIGS. 4B and 4C, respectively, showing the scattered field (|E|²) in the plane above the NW resulting from illumination at normal incidence with a transverse-magnetic plane wave at 633 nm. The optically excited SPP mode is on-resonance and off-resonance in FIGS. 4D and 4E, respectively (scale bars, 200 nm). FIG. 4F is a Raman spectra of methylene blue collected from the planar Au film (dotted line), the off-resonance NW (dashed line), and on-resonance NW (solid line). The region highlighted by the dashed box denotes the spectral range used to generate spatial maps of the Raman intensity. FIGS. 4G and 4H are three-dimensional spatial maps of the relative Raman signal intensity generated by raster scanning a 633 nm laser over on- and off-resonance nanogap-encoded Si/Au structures with segment lengths of about 775 nm (FIG. 4G) and about 1175 nm (FIG. 4H), respectively;

FIGS. 5A-5E are schematic depictions of the synthesis of nanorod-encoded NWs for non-volatile memory, and analytical data pertaining thereto. FIG. 5A is a schematic illustration and flow chart of a sequential process of fabricating a non-volatile memory bit. FIG. 5B is a SEM image of a NW device encoded with a non-volatile memory bit (dashed box) showing Ti/Pd Ohmic contacts on the far left and right (scale bar, 1 um). FIG. 5C is an SEM image (scale bar, 100 nm) of the encoded memory bit corresponding to the dashed white box in FIG. 5C, and corresponding finite-element simulation of the electric field magnitude across the NW at an applied bias of +8 V plotted in a logarithmic color scale for a nanorod segment 50 nm in length and 10 nm in diameter. FIG. 5D is graph plotting the characteristic switching I-V curve for an encoded Si NW memory device. The hatched regions define the ‘set’ and ‘reset’ bias ranges. FIG. 5E is a graph plotting the resistive switching behavior over ten memory cycles. Dashed lines represent the ‘set’/‘reset’ pulses between current readings, which were acquired five times at 1 V between each ‘set’ or ‘reset’ pulse;

FIG. 6 is an Arrhenius plot of the rate of axial VLS NW growth (circles) and rate of radial overcoating (squares). Dashed lines represent the best fit to the Arrhenius equation. Error bars are comparable in size to the marker symbols and were omitted for clarity. The region highlighted by the dashed box denotes a temperature range for synthesis of Si NW structures disclosed herein that can be optimal in some embodiments;

FIGS. 7A and 7B are data outputs based on the analysis of nanophotonic applications of shape-controlled Si NWs. FIG. 7A includes dark-field optical microscopy images of Si NWs with diameters of 100 nm (panel I), 50 nm (panel II), and modulated 100/50 nm segments (panel III) (scale bars, 2 um). FIG. 7B is a dark-field scattering spectrum from NWs I (dotted curve), II (dashed curve), and III (dotted and dashed curve). The solid curve reflects the sum of the spectra from I and II;

FIGS. 8A-8E comprise data outputs and images based on the characterization and analysis of the rate of Si NW growth and overcoating. FIG. 8A is series of SEM images of n-type/intrinsic ‘on’/‘off’ segments formed at growth temperatures of 390° C. (top panel), 405° C. (middle panel), and 420° C. (bottom panel) and etched for 15 seconds with growth times indicated below segments (scale bars, 100 nm). FIG. 8B is a diameter profile acquired from a 420° C. SEM image of the Si NW depicted in the bottom panel of FIG. 8A. FIG. 8C is a histogram of measured VLS growth rates from 360° C. to 450° C. FIG. 8D is a series of SEM images of a Si NW grown at 510° C. exhibiting significant overcoating. Images were taken in increments of 10 μm along the NW growth axis beginning just below the Au catalyst (top image) (scale bars, 50 nm). FIG. 8E is a plot of the measured diameter as a function of growth time for the images in FIG. 8D;

FIGS. 9A and 9B depict results of the analysis of thermal oxidation of Si NWs synthesized as disclosed herein. FIG. 9A includes SEM images of a NW grating before (top panel) and after (bottom panel) thermal oxidation at 1000° C. for 1 minute to form an approximately 15 nm thick thermal oxide layer (scale bars, 200 nm). FIG. 9B is a diameter profile of the NW grating in FIG. 9A before (solid curve) and after (dashed curve) thermal oxidation.

### DETAILED DESCRIPTION

General Discussion

Provided herein are methods and systems to chemically encode high-resolution shapes and morphologies in silicon (Si) nanowires (NWs) during metal nanoparticle growth, including during catalyzed vapor-liquid-solid (VLS) or vapor-solid-solid (VSS) growth. By combining accurate control of NW growth rates with precise in situ phosphorus doping and dopant-dependent wet-chemical etching, the morphology of NWs can be controlled along the growth axis to form geometrical shapes, profiles, nanogaps, and gratings with a size resolution as small as 10 nm. Such high-resolution shapes encoded on NWs can be useful in a plurality of applications as discussed herein. For example, Si NWs as disclosed herein and as produced by methods provided herein can in some aspects be employed as a platform for photonic and electronic technologies.

The bottom-up Si NW synthetic methods and systems provided herein can encode a high-resolution array of arbitrary shapes, including nanorods, sinusoids, bow-ties, tapers, nanogaps, and gratings, along the NW growth axis. These Si NWs are distinct from the conventional Si NWs with a wire, conical and/or tubular symmetry or generally cylindrical morphology.

Si NWs as disclosed herein and as produced by methods provided herein, can be utilized in a variety of photonic, electronic and other technologies. By way of example and not limitation, and as discussed further hereinbelow, nanogap-encoded NWs can be used as templates for Noble metals, yielding plasmonic structures with tunable resonances for surface-enhanced Raman imaging. By way of example and not limitation, and as discussed further hereinbelow, core/shell Si/SiO₂ nanorods can be integrated into electronic devices that exhibit resistive switching, enabling non-volatile memory storage. Additionally, by way of example and not limitation, the disclosed method and systems can be utilized as a generic route to encode new functionality in semiconductor NWs.

### Definitions

While the following terms are believed to be well understood by one of ordinary skill in the art, the following definitions are set forth to facilitate explanation of the presently disclosed subject matter.

Unless defined otherwise, all technical and scientific terms used herein have the same meaning as commonly understood to one of ordinary skill in the art to which the presently disclosed subject matter belongs. Although any methods, devices, and materials similar or equivalent to those described herein can be used in the practice or testing of the presently disclosed subject matter, representative methods, devices, and materials are now described.

Following long-standing patent law convention, the terms “a” and “an” mean “one or more” when used in this application, including the claims.

Unless otherwise indicated, all numbers expressing quantities of ingredients, reaction conditions, and so forth used in the specification and claims are to be understood as being modified in all instances by the term “about”. Accordingly, unless indicated to the contrary, the numerical parameters set forth in this specification and attached claims are approximations that can vary depending upon the desired properties sought to be obtained by the presently disclosed subject matter.

As used herein, the term “about,” when referring to a value or to an amount of mass, weight, time, volume, concentration or percentage is meant to encompass variations of in some embodiments ±20%, in some embodiments ±10%, in some embodiments ±5%, in some embodiments ±1%, in some embodiments ±0.5%, and in some embodiments ±0.1% from the specified amount, as such variations are appropriate to perform the disclosed method.

As used herein, the term “and/or” when used in the context of a listing of entities, refers to the entities being present singly or in combination. Thus, for example, the phrase “A, B, C, and/or D” includes A, B, C, and D individually, but also includes any and all combinations and subcombinations of A, B, C, and D.

The term “comprising”, which is synonymous with “including,” “containing,” or “characterized by” is inclusive or open-ended and does not exclude additional, unrecited elements or method steps. “Comprising” is a term of art used in claim language which means that the named elements are present, but other elements can be added and still form a construct or method within the scope of the claim.

As used herein, the phrase “consisting of” excludes any element, step, or ingredient not specified in the claim. When the phrase “consists of” appears in a clause of the body of a claim, rather than immediately following the preamble, it limits only the element set forth in that clause; other elements are not excluded from the claim as a whole.

As used herein, the phrase “consisting essentially of” limits the scope of a claim to the specified materials or steps, plus those that do not materially affect the basic and novel characteristic(s) of the claimed subject matter.

With respect to the terms “comprising”, “consisting of”, and “consisting essentially of”, where one of these three terms is used herein, the presently disclosed and claimed subject matter can include the use of either of the other two terms.

As used herein, “significance” or “significant” relates to a statistical analysis of the probability that there is a non-random association between two or more entities. To determine whether or not a relationship is “significant” or has “significance”, statistical manipulations of the data can be performed to calculate a probability, expressed as a “p value”. Those p values that fall below a user-defined cutoff point are regarded as significant. In some embodiments, a p value less than or equal to 0.05, in some embodiments less than 0.01, in some embodiments less than 0.005, and in some embodiments less than 0.001, are regarded as significant. Accordingly, a p value greater than or equal to 0.05 is considered not significant.

As used herein, the term “high-resolution”, when used to refer to shapes, structures, elements and/or morphologies on NWs, relate to the detail and scale of the encoded shapes, structures, elements and/or morphologies on a synthesized NW. As demonstrated herein “high resolution” features can have a length scale as small as 10 nm. In some embodiments, “high-resolution” can refer to an encoded shape having a scale or size of about 1,000 nm to about 10 nm, or about 500 nm to about 10 nm, or about 100 nm to about 10 nm, or about 50 nm to about 10 nm. In some embodiments, “high-resolution” can refer to accurate, nanometer-scale control of morphology, e.g. shapes, in single-crystalline semiconductor NWs.

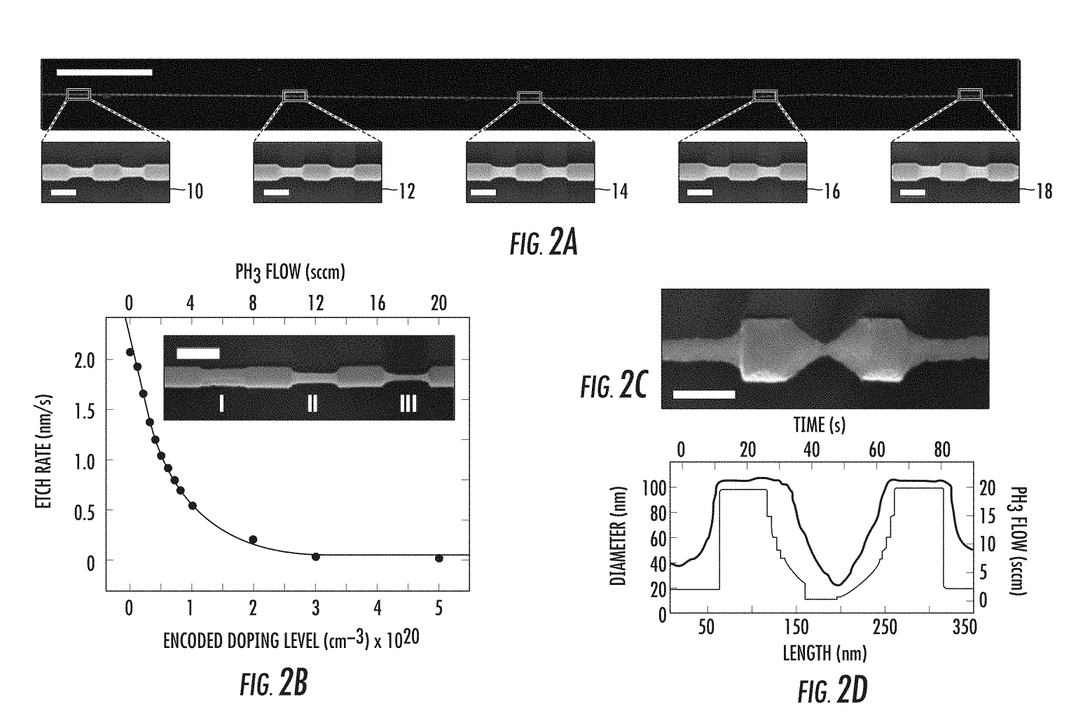

As used herein, the term “high fidelity” refers to the ability to repeat the same “high-resolution” features many times along one nanowire, and/or the ability to create the same “high-resolution” feature across many different nanowires. For example, FIG. 2A shows approximately 125 individual “high-resolution” features encoded along a nanowire that is 50,000 nm long.

Synthesis and Uses of Encoded Silicon Nanowires

NWs can be synthesized using the vapor-liquid-solid (VLS) mechanism (Wagner et al., 1964), in which a metal nanoparticle catalyzes one-dimensional growth of a single-crystalline semiconductor material. Unfortunately, until the instant disclosure there has not been a method for accurate, nanometer-scale control of morphology, e.g. shapes, in single-crystalline semiconductor NWs. Thus, disclosed herein are methods and systems to achieve this type of high-fidelity shape control is Si NWs.

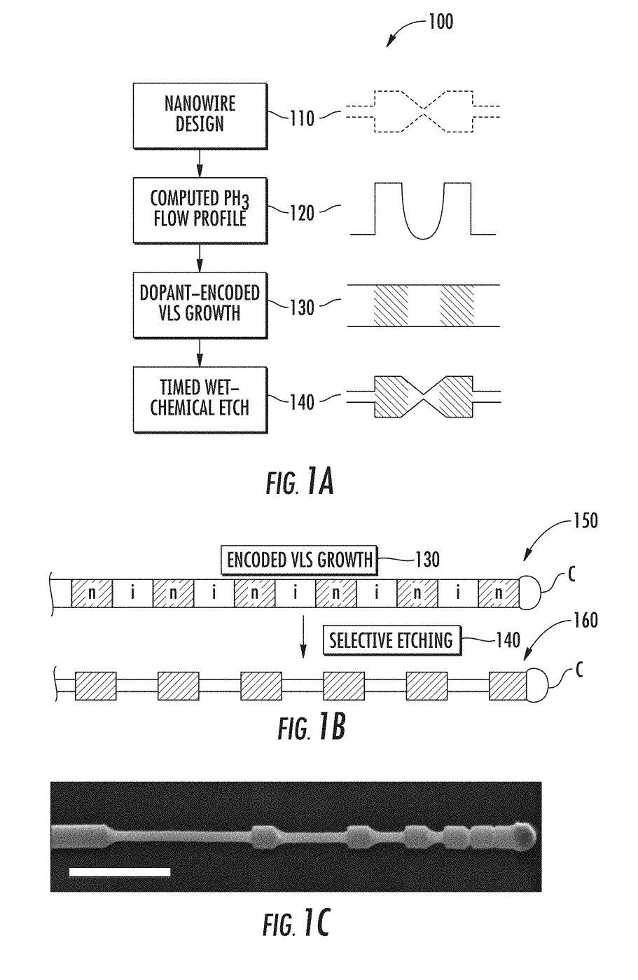

To elaborate, in some embodiments the instant disclosure provides strategies for chemical synthesis of high-resolution, nanometer-scale features and/or shapes in silicon NWs, as illustrated in FIGS. 1A-1C. Through a combination of calibrated growth rates, precise dopant incorporation, and dopant-dependent chemical etching, the shape of NWs can be controlled on length scales ranging from about 1 to about 1,000 nm.

Nanophotonics is a field of research concerned with the manipulation of light on length scales smaller than its wavelength and with the miniaturization of optical elements so they can be directly integrated into compact on-chip architectures (Benson, 2011; Sorger et al., 2012; Brongersma et al., 2010; Ozbay, 2006; Zia et al., 2006; Barnes et al., 2003; Schuller et al. 2010; Hess et al., 2012; de Leon et al., 2012; Beausoleil et al., 2008). Basic nanophotonic structures include waveguides to control light propagation and photodetectors for photon-to-electron signal transduction (Sorger et al., 2012; Beausoleil et al., 2008). To achieve these functions, nanophotonic devices often incorporate a variety of materials, including dielectrics and metals. These devices encompass both photonic crystal and plasmonic structures (Benson, 2011; Sorger et al., 2012; Brongersma et al., 2010; Ozbay, 2006; Zia et al., 2006; Barnes et al., 2003; Halas, et al., 2012; Lindquist et al., 2012; Novotny et al., 2011; Hutter & Fendler, 2004) and typically rely on high-cost, low-throughput lithographic procedures to produce working devices (Lindquist et al., 2012. As an alternative, some embodiments of the present disclosure allow for the circumvention of the need for advanced lithography by synthetically encoding high-resolution (1 to 1,000 nm) nanophotonic structures directly along the growth axis of semiconductor NWs.

In some aspects, by using carefully controlled synthetic conditions, complex structures typically produced only by advanced electron-beam lithography can be formed in parallel on many, e.g. millions, of identical NWs by a robust and highly reproducible synthetic method. The disclosed well-controlled, precise in situ doping of Si during VLS, or vapor-solid-solid (VSS), growth of Si NWs allows for the encoding of dielectric waveguides, plasmonic waveguides, and detector elements within individual NW structures. By way of example and not limitation, demonstrated herein is a NW encoded with a dielectric grating with tunable pitch size as small as 20 nm. In addition, demonstrated herein is a NW p-n junction photodetector with tunable, wavelength-selective photoresponse. The development of methods to synthesize high-resolution, morphologically-controlled NW structures, as provided herein, can in some embodiments allow for a new class of complex, chip-based photonic and plasmonic systems that use NWs as the low-cost, nanophotonic building blocks for more complex architectures.

To achieve the chemical synthesis of high-resolution, nanometer-scale features in silicon NWs disclosed herein are methods and systems for encoding nanowire growth and appearance using VLS-based growth (or VSS-based growth) and etching. In some aspects, such a methodology can be referred to as “ENGRAVE” (Encoded Nanowire GRowth and Appearance using VLS-growth and Etching).

Turning now to the figures, FIG. 1A is a flow-chart and corresponding schematic depiction of the sequential process for synthesis of NW morphologies as disclosed herein. As depicted in FIG. 1A, in some embodiments a method of synthesizing 100 Si NWs with encoded morphologies and/or features can comprise designing 110 a NW with a desired morphology, shape or feature; computing 120 a phosphorous (e.g. PH₃), or boron, flow profile to achieve the desired morphology, shape or feature; performing dopant-encoded VLS growth 130; and etching (wet-chemical) 140 the NW to reveal the desired morphology, shape or feature. As depicted in FIG. 1B, VLS (or VSS) NW growth 130 with an Au catalyst C can comprise rapid modulation of P dopant (or boron dopant) incorporation to form heavily-doped n-type n and undoped intrinsic i segments in an unetched NW 150 that can be selectively etched 140 using wet-chemical methods to form a Si NW 160 with the desired morphology, shape or feature. The results of such a method are depicted in FIG. 1C which is a scanning electron microscope (SEM) image of an exemplary NW grating encoded (from left to right) with sequential intrinsic segments for 200, 100, 50, 25, 10, and 5 seconds (scale bar, 500 nm).

The methods illustrated in FIGS. 1A-1C and described further herein provide significant advantages over existing methods of synthesizing Si NWs, including for example the never before demonstrated high-resolution morphological control of the synthesis of Si NWs using VLS and/or VSS growth mechanisms. Compared to electrodeposited wires, VLS-grown (or VSS) NWs are hundreds of microns in length, providing the scale relevant to surface plasmon propagation and device integration and are composed of Si, the material most technologically compatible with current semiconductor manufacturing. Additionally, the disclosed Si NW synthetic methodologies are not limited to one design but instead enable a diverse range of morphologically-controlled structures, shapes, profiles and features over multiple length scales, including for example gratings with variable pitch and grating depth, nanogaps with tunable gap size, and tapered structures including nanoscale bow-ties. Finally, using the disclosed Si NW synthesis methods, high resolution morphological structures can be incorporated with active photodetectors, such as avalanche p-n junction photodiodes, on the same NW, providing an “all-in-one” route to optical waveguides directly coupled to optical detectors for photon-to-electron signal transduction.

The synthesis of Si NWs with encoded morphologies by chemical vapor deposition is disclosed herein, including in the examples. Generally, a chemical vapor deposition (CVD) system can be used for synthesis of Si NWs. For example, a hot-wall low-pressure CVD system capable of bottom-up synthesis of complex Si or Ge NW structures can be utilized. Such a system can be capable of growing NWs in areas of greater than 5 cm², which can correspond to the growth of about 30 million individual NWs. Such a system, with a base pressure of less than 1×10⁻⁴ Torr, can contain the gases SiH₄, GeH₄, B₂H₆, PH₃, HCl, Ar, and/or H₂ each with independent, computer-controlled flow control. In some embodiments, H₂ and Ar can be used as carrier gases, SiH₄ and GeH₄ as the source gases for Si and Ge, respectively, B₂H₆ to dope structures p-type, PH₃ to dope structures n-type, and HCl for in situ etching of as-grown semiconductors. Gas flow rates, reactor temperature, and reactor pressure can in some aspects be computer-controlled using a software application or computerized program, e.g. Labview software, thereby permitting fully programmable, automated NW growth and, importantly, reproducible synthesis of complex, high-resolution NW structures. In some embodiments, and as evidenced by the examples herein, the reactor temperature can range from about 25° C. to about 1,100° C., and reactor pressure from about 0.25 Torr to about 1,000 Torr. A custom-built system encompassing the features above, such as that utilized in the disclosed experiments, can allow one synthetic run to encompass a broad range of synthetic conditions.

Si NWs and synthesized structures can in some embodiments be characterized in detail using scanning electron microscopy (SEM), transmission electron microscopy (TEM), as well as atomic force microscopy (AFM). Such instruments can enable rapid evaluation of as-synthesized nanostructures and devices. Moreover, experimental electrical and optical characterization of synthesized Si NWs can be performed using a variety of equipment, including for example standard electron-beam lithographic procedures and electron-beam evaporation to produce metal contacts to single NWs, and wire bonder systems for macroscopic connections. Electrical measurements can be acquired with a sourcemeter. The photocurrent response of individual NWs under different illumination wavelengths can be measured using an incident-photon-to-current-efficiency (IPCE) optical setup. Further analysis can comprise the use of microscopes capable of bright-field and dark-field imaging. For more advanced far-field optical characterization of photonic and plasmonic NWs as disclosed herein, a laser-scanning optical microscope/spectrometer capable of scanning a diffraction-limited laser beam over the NW structures and collecting the spectrum of light scattered by the NW concurrent with a high-resolution dark field image can be used.

Continuing with the synthesis of high-resolution NW structures, in some embodiments such NW growth can be achieved by VLS or VSS growth mechanisms. Although NWs are often grown by a VLS mechanism in which a liquid Au—Si eutectic alloy is used as the catalyst for one-dimensional growth of NWs, the presently disclosed subject matter provides methods of synthesizing high-resolution NW structures using VSS. Particularly, the growth rate has been quantitatively measured as a function of temperature for Si NWs during VSS growth with an Au catalyst. From this data, it was determined that the activation energy for the process, at 152 kJ/mol, is substantially different from the activation energy for VLS growth, at 83 kJ/mol. Although not wishing to be bound by any particular theory or mechanism of action, the origin of this difference is likely a result of differing rates of decomposition on the Au versus Au/Si surface combined with effects from the diffusion of Si species and the kinetics of solid Si deposition at the catalyst/NW interface.

For the disclosed CVD growth conditions, an exemplary rate in VSS mode is in the range of 0.1-2 nm/min, and this slow growth rate permits the encoding of ultra-sharp dopant transitions. Thus, by understanding the growth rates in both VLS and VSS growth modes the instant disclosure provides for the creation of ultra-sharp, high-resolution morphological features in Si NWs that have direct applications as photonic and plasmonic structures.

A CVD system such as that discussed herein can provide for the growth of Si NWs with highly controlled doping levels ranging from 5×10²⁰ cm⁻³ to below 1×10¹⁸ cm⁻³. This high level of synthetic control is enabled by the careful design of the CVD system with high-accuracy, fast-response mass-flow controllers responsive over a broad flow range. The flow rates of SiH₄ and PH₃ can in some embodiments be adjusted on a timescale of less than 1 second, permitting rapid alteration of the n-type (phosphorus) doping level (See, e.g., FIG. 1B). KOH solution is a well-known etchant for Si (Seidel et al., 1990). As such, the dependence of the etch rate on n-type doping level is exploited in order to morphologically control the shape of NWs. Thus, as depicted in FIG. 1A, Si NWs with encoded morphological features can be synthesized using a procedure that can in some embodiments involve the following steps: 1) VLS (or VSS) growth of a Si NW encoded with variable doping levels along its growth direction, 2) mechanical transfer of the NWs from the growth substrate to secondary substrate, and 3) timed etching of the NWs in KOH solution to reveal the high-resolution morphology encoded by the dopants.

The etch rate of Si NWs at different doping levels has been carefully measured, as depicted in FIG. 2B. Particularly, FIG. 2B is a graph plotting the radial etch rate of Si NWs as a function of encoded P doping levels (curved line represents the best fit to a single exponential function), with an inset SEM image of a NW with segments I, II, and III encoded with P doping levels of 1×10²⁰ cm⁻³, 5×10¹⁹ cm⁻³, and intrinsic, respectively, and etched for 25 seconds (scale bar, 200 nm). As shown in the SEM image of FIG. 2B, the doping level has a dramatic effect on the extent of etching of the NWs, permitting the building of the doping-dependent etch rate calibration curve depicted in FIG. 2B. Using this calibration curve, any desired structure or morphology in the Si NWs can be created, as demonstrated herein. By building this data, the presently disclosed methods provide for the ability to encode a broader range of NW photonic and plasmonic structures, including for example a bow-tie as depicted and analyzed in FIG. 2C-2D.

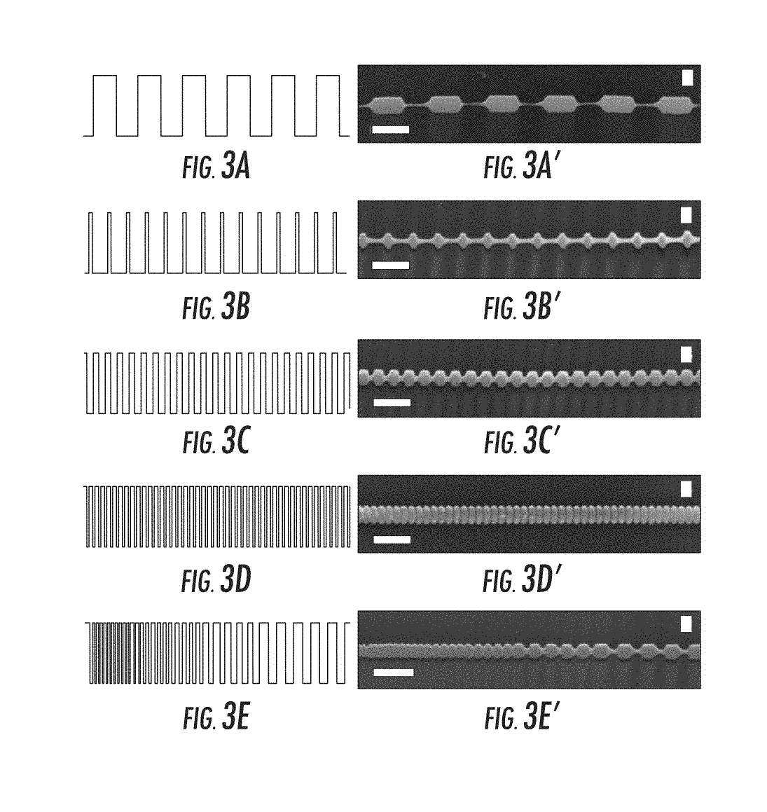

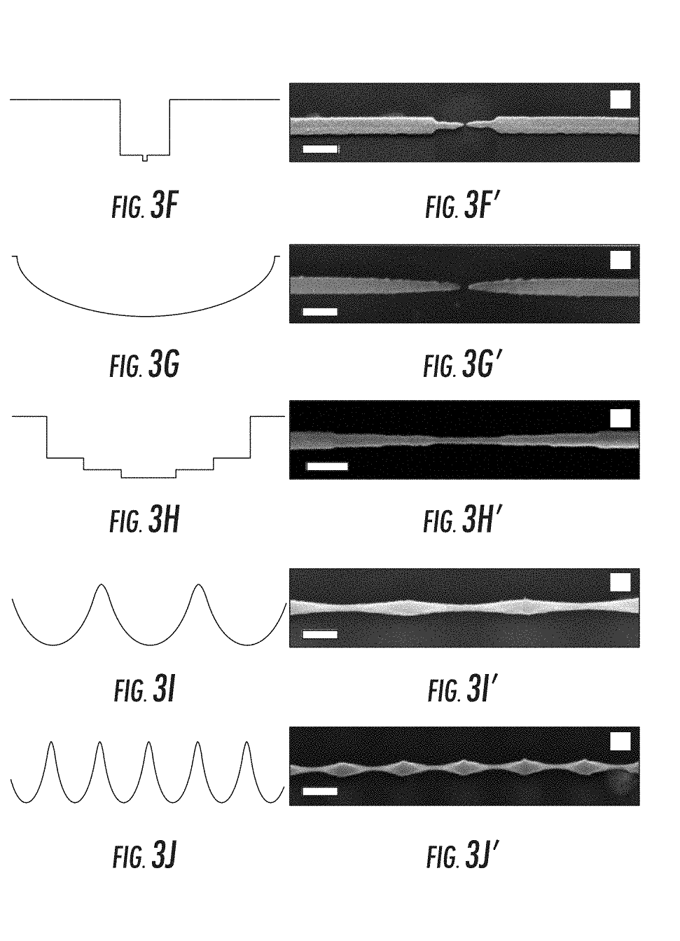

As depicted in FIGS. 3A-3J, and corresponding FIGS. 3A′-3J′, Si NWs with a range of morphologies, shapes and features can be created as desired and as needed for a given application. In particular, FIGS. 3A-3J, and corresponding FIGS. 3A′-3J′, depict a series of phosphine flow profiles (FIGS. 3A-3J) for the synthesis of Si NWs with complex morphology, and SEM images (FIGS. 3A′-3J′) of the Si NWs synthesized using each phosphine flow profile (all scale bars, 200 nm; flow rates vary from 0 to 20 sccm for each NW). These structures include periodic (FIGS. 3A′-3D′) or non-periodic (FIG. 3E′) gratings, nanogaps with gap sizes as small as 10 nm (FIGS. 3F′-3G′), suspended nanorods (FIG. 3H′), and sinusoidal profiles (FIGS. 3I′ to 3J′).

Such NWs can in some aspects be synthesized using the VLS growth mechanism to encode multiple n-type/intrinsic/n-types segments that can subsequently be etched, as discussed herein and depicted in FIGS. 1A-1C. Because of the detailed calibration of the NW growth rate disclosed herein, etched segments greater than 1 micron or as small as about 10-20 nm in length can be encoded within the same NW. Furthermore, such grating structures or features can be encoded over the entire length of a NW, including a NW of greater than 100 microns (see, e.g., FIG. 2A).

The exemplary morphologies illustrated in FIGS. 3A′-3J′ can in some embodiments provide for various classes of NW-based technologies. By way of example and not limitation, the suspended nanorods (FIG. 3H′) could be used as mechanical oscillators for nanoelectromechanical systems, periodic gratings (FIGS. 3A′-3D′) for optical applications in nanophotonics, and non-periodic gratings (FIG. 3E′) as a method to control thermal transport along the wires, enabling the use of Si as a thermoelectric material.

Although gratings, as discussed above, are widely used in nanophotonic systems, there is also substantial interest and utility for non-periodic nanoscale structures that give rise to strong electric field enhancements. For example, nanoscale Au bow-tie structures can in some aspects give rise to intense electric field distributions that can be used for field-enhanced spectroscopy. Similarly, tapered structures can in some embodiments be capable of nanofocusing or concentrating a propagating surface plasmon excitation. Furthermore, tapered NW plasmonic structures can in some aspects be used as the basis for single photon transistors and used as coupling elements between photonic waveguide and plasmonic waveguide systems. Thus, there are a substantial number of technological applications for a quasi-one-dimensional wire encoded with morphological features that yield strong, unique electric field interactions, as provided herein.

Thus, by combining calibrated NW growth rates with calibrated etch rates, and the capability to encode rapid changes in doping level with a CVD system, the presently disclosed methods and systems of synthesizing encoded Si NWs provides the ability to directly encode any desired structure in Si NWs. Particularly, in some embodiments, methods of chemically encoding high-resolution shapes in Si NWs during metal nanoparticle catalyzed VLS growth or VSS growth are provided. Such methods can comprise: growing Si NWs using VLS or VSS growth in a chemical vapor deposition system at a predetermined growth rate, controlling in situ phosphorus or boron doping of the Si NWs during the growth of the Si NWs, and etching the Si NWs to form high-resolution shapes along a growth axis on the Si NWs.

In some embodiments, growing Si NWs at a predetermined growth rate can comprise growing the Si NWs at a temperature of about 200° C. to about 1,000° C., a pressure of about 100.0 mTorr to about 500.0 Torr, using a nanoparticle catalyst having a diameter of about 5 nm to about 500 nm, using Si gas as the Si source at a flow of about 0.15 to about 10.00 standard cubic centimeters per minute, and using hydrogen as a carrier gas at a flow of about 10.0 to about 400.0 standard cubic centimeters per minute. In some embodiments, the temperature can range from about 200° C. to about 1,000° C., about 300° C. to about 800° C., about 400° C. to about 600° C., or about 400° C. to about 450° C. In some embodiments, the pressure can range from about 100.0 mTorr to about 500.0 Torr, about 1 Torr to about 200.0 Torr, about 10.0 Torr to about 100.0 Torr, or about 20.0 Torr to about 50.0 Torr. In some embodiments, the nanoparticle catalyst can have a diameter of about 5 nm to about 5 microns, about 5 nm to about 1 micron, about 5 nm to about 500 nm, about 10 nm to about 250 nm, or about 50 nm to about 150 nm. In some embodiments, the flow of Si gas can range from about 0.15 to about 10.0 standard cubic centimeters per minute, about 0.5 to about 5.0 standard cubic centimeters per minute, or about 1.0 to about 3.0 standard cubic centimeters per minute. In some embodiments, the flow of hydrogen can range from about 10.0 to about 400.0 standard cubic centimeters per minute, about 50.0 to about 300.0 standard cubic centimeters per minute, or about 100.0 to about 250.0 standard cubic centimeters per minute.

In some embodiments, growing Si NWs at a predetermined growth rate can comprise growing the Si NWs at a temperature of about 420° C., a pressure of about 40.0 Torr, using a nanoparticle catalyst of about 100 nm in diameter, with the flow of Si gas at about 2.0 standard cubic centimeters per minute, and the flow of hydrogen gas at about 200.0 standard cubic centimeters per minute. Alternative, or in addition, in some embodiments, growing Si NWs at a predetermined growth rate can comprise growing the Si NWs at a temperature of about 420° C., a pressure of about 20.0 Torr, using a nanoparticle catalyst of about 100 nm in diameter, with the flow of Si gas at about 2.0 standard cubic centimeters per minute, and the flow of hydrogen gas at about 100.0 standard cubic centimeters per minute.

In some aspects, the Si gas used in the above-described methods can comprise any Si gas known and/or available, including for example silane (SiH₄), disilane (Si₂H₆) and silicon tetrachloride (SiCl₄). Such Si gases can also be expressed as SiHₓCl₄₋ₓ and Si(CH₃)ₓCl₄₋ₓ (where x=0, 1, 2, 3, or 4), which encompasses all the Si gases as well as the high vapor pressure liquids that can be used for this type of growth.

In some embodiments, GeH₄ can be used in place of Si gas so as to form Ge NWs using the same methodology as that used to synthesize Si NWs.

In some embodiments, the catalyst described in the above methods can comprise a solid or liquid. In some embodiments, the solid catalyst can be selected from the group consisting of Au, Ag, Ti, Co, Cd, Dy, Gd, Mg, Mn, Os, Pr, Ru, Fe, Ni, Pt, Pd, Te, Cu, Sb, Al, Zn, Au, Pb, TI, Bi, Sn, In, Ga, and alloys thereof. In some embodiments, the liquid catalyst can be selected from the group consisting of Au, Ag, Ti, Co, Cd, Dy, Gd, Mg, Mn, Os, Pr, Ru, Fe, Ni, Pt, Pd, Te, Cu, Sb, Al, Zn, Au, Pb, TI, Bi, Sn, In, Ga, and alloys thereof.

In some embodiments the step of controlling in situ phosphorus doping during the growth of the Si NWs can comprise controlling the flow of phosphine gas (PH₃) or similar gas-phase phosphorus precursor (e.g., PCl₃ which is a liquid at room temperature but has low boiling point and high vapor pressure) at about 0.15 to about 20.00 standard cubic centimeters per minute. This step can also comprise rapidly modulating the flow during Si NW growth to encode varying levels of phosphorus, wherein the PH₃ is diluted to about 1,000 ppm in hydrogen or other inert gas. This rapid modulation of the flow of phosphine gas allows for the encoding or doping as depicted in FIGS. 1A-1C, for example. Likewise, in some aspects controlling in situ boron doping during the growth of the Si NWs can comprise controlling the flow of diborane gas (B₂H₆), or similar gas-phase boron precursor (e.g., B(CH₃)₃ and BCl₃; both have boiling points just below room temperature), at about 0.15 to about 100.00 standard cubic centimeters per minute, wherein the flow is rapidly modulated during Si NW growth to encode varying levels of boron, wherein the B₂H₆ is diluted to about 10 to about 10,000 ppm in hydrogen or other inert gas.

While the flow rates for various gases discussed herein are intended to be exemplary in nature, one of skill in the art will appreciate that relative amounts of the gases can in some embodiments be more meaningful than the actual flow rates, and partial pressures can in some aspects be more meaningful than the total pressure. As such, in some embodiments flow rates and pressures of gases, and all other conditions, can be adjusted or optimized to produce stable VLS or VSS growth without departing from the scope of the instant disclosure.

In some aspects, etching the Si NWs to form high-resolution shapes along a growth axis on the Si NWs can comprise wet etching using potassium hydroxide (KOH) solution. As an alternative to KOH, in some embodiments a similar alkaline solution using LiOH, NaOH or organic etchants including ehtylenediamine and hydrazine can be used. Importantly, the etch rate of the phosphorus or boron doped Si of the Si NW decreases with higher phosphorus or boron dopant concentration. Thus, this rate dependent etching causes increased removal of Si in regions of the Si NWs that are more lightly doped as compared to those regions more highly doped thereby creating high-resolution structures along the growth axis of the Si NW.

The high-resolution shapes that are encoded in the Si NWs synthesized by the disclosed methods can comprise any shape, configuration or morphology that is desired, including for example geometrical shapes, conical profiles, nanogaps and gratings. The high-resolution shapes that are encoded in the Si NWs can have a size resolution of about 1,000 nm to about 10 nm. In some embodiments, “high-resolution” is considered a shape or morphological element with a size resolution of about 500 nm to about 10 nm, or about 100 nm to about 10 nm.

In some aspects, the method of synthesizing encoded Si NWs can further comprise thermal oxidation of the Si NW, and deposition of a metal film on the Si NW. In some aspects, Si NWs can be used as a template for metal films, whereby application of a metal film to the Si NW provides a hybrid metal/dielectric nanostructure that supports surface plasmon resonances.

Thus, in some aspects provided herein are silicon nanowires comprising high-resolution shapes, comprising a silicon nanowire of about 5 nm to about 500 nm diameter having a growth axis, and a high-resolution shape, profile, nanogap, grating or combination thereof along the growth axis, wherein the high-resolution shape, profile, nanogap, grating or combination thereof has a resolution of about 10 nm to about 1,000 nm. In some aspects, such a silicon nanowire can have a plurality of repeating shapes, profiles, nanogaps, gratings or combinations thereof, wherein the repeating shapes, profiles, nanogaps, gratings or combinations thereof are spaced apart by about 10 nm to about 10,000 nm. Such nanowires can have a length of up to about 50 to about 500 microns.

In some embodiments, the disclosed robust strategy to encode complex shapes in Si NWs can be used to design and synthesize bottom-up nanophotonic structures with specific optical characteristics. In some aspects, the shape of a NW feature or element can substantially influence the interaction of light with these nanostructures. For NWs with diameters in the range of about 50 nm to about 500 nm, it is known that small changes in size and shape can substantially alter absorption (Kim et al., 2012) and scattering properties (Bronstrup et al., 2010). As shown by the dark-field optical microscopy and SEM images in FIG. 7A, NWs synthesized with diameters of 100 nm (I), 50 nm (II), and alternating 100/50 nm segments (III), appear light, dark, and the alternating light/dark, respectively. Measurement of the scattering spectrum from NWs I and II (FIG. 7A) yield distinct spectra, and the spectrum of the modulated NW (panel III of FIG. 7A) is a weighted sum of I and II, as illustrated in FIG. 7B. Thus, in some embodiments the disclosed methods of encoding shapes and morphologies in Si NWs can be used to design and synthesize nanophotonic structures with specific optical characteristics.

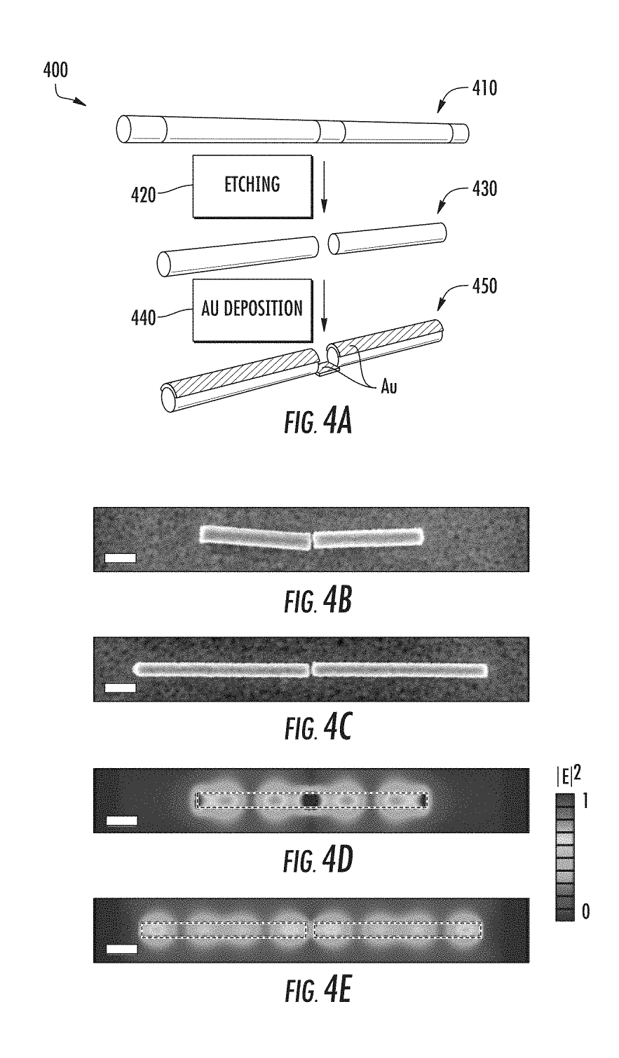

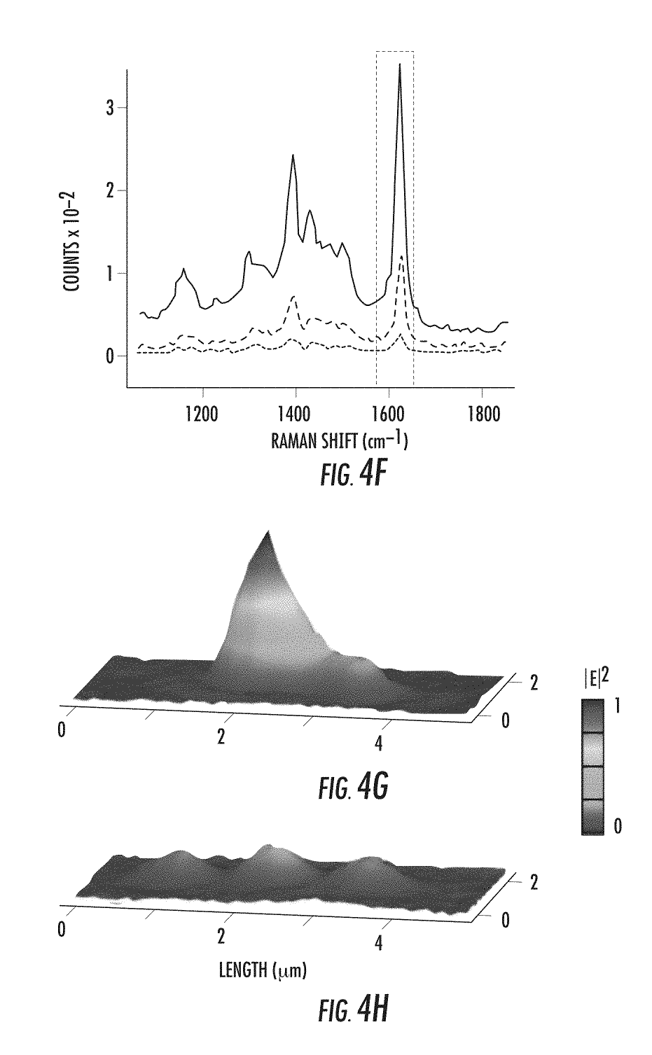

Likewise, in some aspects the disclosed methods of encoding shapes and morphologies in Si NWs can be used to design and synthesize Si NWs with nanoplasmonic structures. Field-enhanced spectroscopies, such as surface-enhanced Raman spectroscopy (SERS), are often performed using Noble metal nanostructures that support surface plasmon polaritons (SPPs) (Willets et al., 2007). Through careful design of the shape of a nanostructure, SPP resonances can be used to confine and amplify incident electromagnetic fields at specific wavelengths and spatial positions (Schuller et al., 2010). Thus, in some embodiments, following the procedure depicted in FIG. 4A, for example, can allow for nanogap-encoded NWs to be used as the topological templates for Noble metal films, thereby creating Si/Au nanostructures with tunable SPP resonances.

Starting from a Si NW with dielectric grating structures, such as those shown in FIGS. 3A and 3A′, a plasmonic grating can be created by physical vapor deposition of an about 50 nm of high-quality metal film, such as for example gold (Au) or silver (Ag), on top of the NW structures. The synthesis an exemplary Au grating structure, and subsequent analysis thereof, is depicted in FIGS. 4A-4H. To elaborate, FIGS. 4A-4H are schematic depictions of the synthesis of nanogap-encoded NWs for plasmonics, and analytical data pertaining thereto. FIG. 4A is a schematic illustration and flow chart of a process of gold (Au) deposition on a nanogap-encoded NW. Particularly, in some embodiments a method of synthesizing nanogap-encoded NWs for plasmonics 400 can comprise providing or synthesizing a dopant-encoded VLS-grown Si NW 410, wet-chemical etching 420 to provide a grated or encoded Si NW core 430, and gold Au (or silver, Ag) deposition 440 to provide a gold Au deposited nanogap-encoded NW 450.

FIGS. 4B and 4C are SEM images of nanogap-encoded Si NWs with 50 nm Au, gaps of about 30 nm, and segment lengths of about 775 nm (FIG. 4B) and about 1175 nm (FIG. 4C) (scale bars, 200 nm). FIGS. 4D and 4E are finite-element optical simulations of the Si/Au nanogap structures depicted in FIGS. 4B and 4C, respectively, showing the scattered field (|E|²) in the plane above the NW resulting from illumination at normal incidence with a transverse-magnetic plane wave at 633 nm. The optically excited SPP mode is on-resonance and off-resonance in FIGS. 4D and 4E, respectively (scale bars, 200 nm). FIG. 4F is a Raman spectra of methylene blue collected from the planar Au film (dotted line), the off-resonance NW (dashed line), and on-resonance NW (solid line). The shaded region denotes the spectral range used to generate spatial maps of the Raman intensity. FIGS. 4G and 4H are three-dimensional spatial maps of the relative Raman signal intensity generated by raster scanning a 633 nm laser over on- and off-resonance nanogap-encoded Si/Au structures with segment lengths of about 775 nm (FIG. 4G) and about 1175 nm (FIG. 4H), respectively. Note that the plasmonic structures depicted and analyzed in FIGS. 4A-4H were formed using entirely bottom-up synthetic techniques and without any lithographic procedures.

As shown by the SEM images in FIGS. 4B and 4C, deposition of about 50 nm of Au on the NWs by physical vapor deposition preserved the high-resolution structures and nanogap morphology. Finite-element optical simulations (see FIGS. 4D and 4E) were used to design Si/Au Si NW structures with specific SPP characteristics. The NWs can behave as plasmonic resonator antennas (Barnard et al., 2008), in which the length of the segments adjacent to the gap control the field enhancement as a result of constructive or destructive interference of the SPP wave along the NW axis (Pedano et al., 2010; Li et al., 2010). For a wavelength of 633 nm, segments of about 775 nm in length were found to be on-resonance, producing intense fields in the gap, while segments about 1175 nm in length were off-resonance, exhibiting weaker field enhancement.

SERS imaging was performed on the Si/Au NWs coated with methylene blue. A greater than ten-fold Raman signal enhancement was observed from the on-resonance structure, as shown by the spectra in FIG. 4F. In addition, Raman imaging (see FIGS. 4G and 4H) confirmed that the signal enhancement is localized to a narrow spatial region around the gap. In comparison, the off-resonance NW showed a weak Raman signal arising from both the gap and the two ends of the rods, a result that is in good agreement with the optical simulations in FIGS. 4D and 4E. These results highlight the capability for the disclosed methods and systems for synthesizing Si NWs to serve as a route or mechanism to create nanoplasmonic structures with tunable resonances applications such as field-enhanced spectroscopy and nanophotonic technologies.

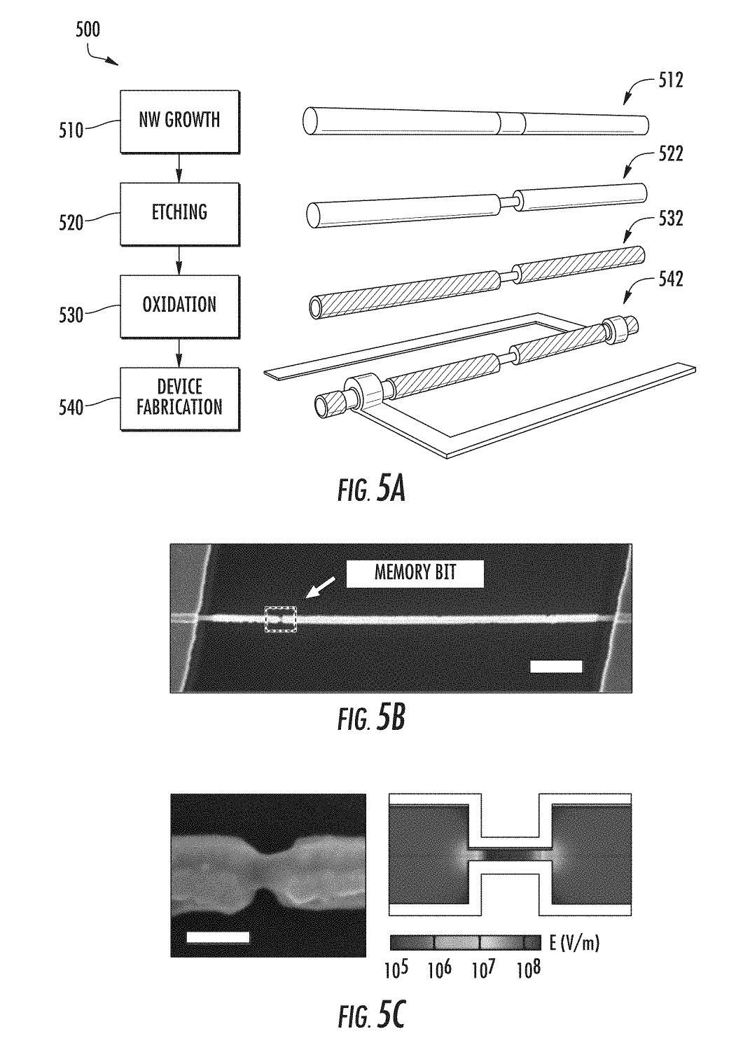

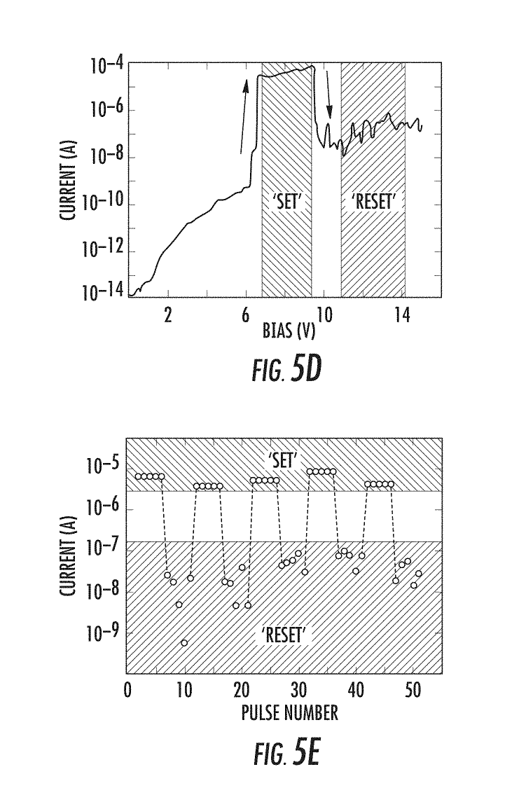

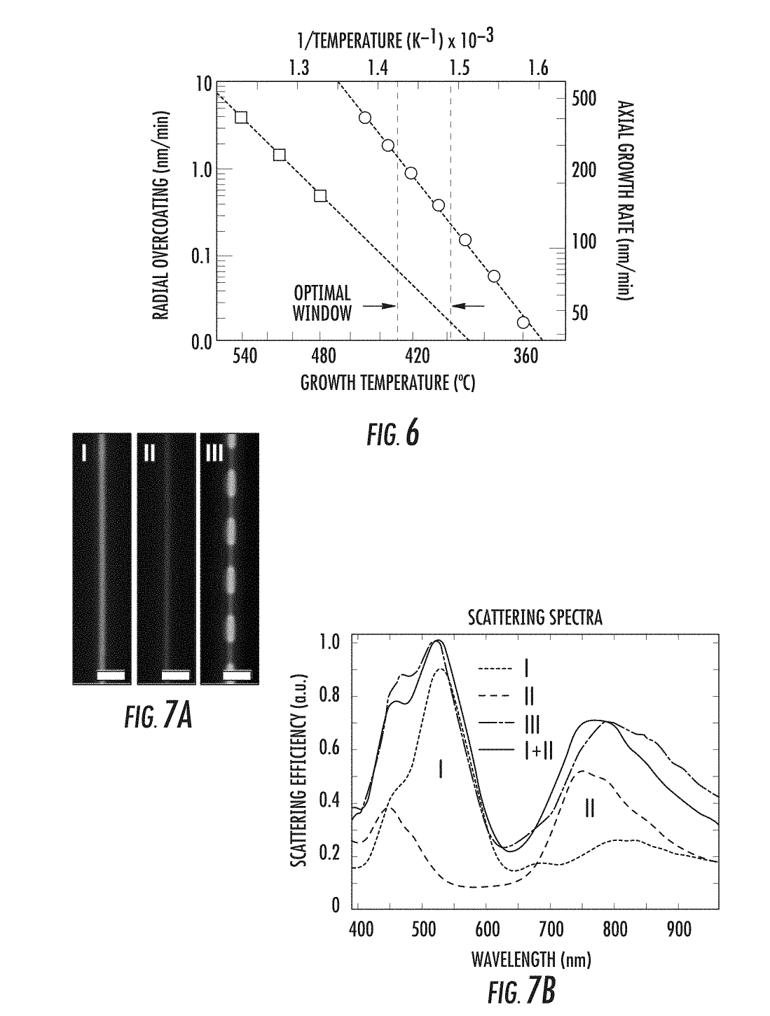

Still yet, in some aspects the disclosed methods of encoding shapes and morphologies in Si NWs can be used to design and synthesize Si NWs with morphologies imparting desired electronic characteristics. For example, in some embodiments core/shell Si/SiO₂ nanorod-encoded devices can be synthesized for use as resistive switches in non-volatile memory. The fabrication steps can comprise those illustrated in FIG. 5A. Particularly, FIG. 5A is a schematic illustration and flow chart of a sequential process of fabricating a non-volatile memory bit. Thus, in some embodiments a method 500 of fabricating a non-volatile memory bit can comprise controlled NW growth 510 to form an encoded Si NW 512, wet-chemical etching 520 to form an etched Si NW 522, oxidation 530 to form an etched Si NW with a silicon oxide layer 532, and device fabrication 540 to form a non-volatile memory bit 542. In some aspects, controlled NW growth 510 can comprise Si NW design and encoded growth as disclosed herein and depicted in FIG. 1A for example.

The oxidation 530 can in some aspects be used to create a Si NW with an Si core encased by an oxide shell 532. As illustrated in FIGS. 9A and 9B, an Si NW can be thermally oxidized to create an about 10 nm diameter Si core encased by an oxide shell. In FIG. 9A SEM images of a NW grating are shown before (top panel) and after (bottom panel) thermal oxidation at 1000° C. for 10 min to form an about 15 nm thick thermal oxide layer (scale bars, 200 nm). FIG. 9B shows the diameter profile of the NW gratings in FIG. 9A before (solid line) and after (dashed line) thermal oxidation.

In some aspects, device fabrication 540 can comprise fabricating electrical contacts to n-type segments adjacent to the intrinsic channel, as shown by the SEM image in FIG. 5B, for example. Device simulations (see FIG. 5C) indicate that this geometry concentrates the voltage drop and electric field within the narrow channel region, enabling a resistive switching effect as observed in a planar Si/SiO₂ system. Thus, in some aspects provided herein are resistive switching memory devices comprising encoded Si NWs. As illustrated in FIGS. 5D and 5E, nanorod-encoded devices can be used as non-volatile memory. Such devices and capabilities are possible due to the disclosed electronic characteristics of Si NWs that can be encoded through morphology.

Thus, in some embodiments provided herein is a nanophotonic or plasmonic structure for use in nanophotonics or plasmonics comprising a Si NW comprising high-resolution shapes along the axis of the NW. As with the other Si NWs disclosed herein, the high-resolution shapes can comprise shapes, profiles, nanogaps, gratings or combinations thereof having a resolution of about 10 nm to about 1000 nm.

The presently disclosed subject matter also provides microelectromechanical (MEMS) or nanoelectromechanical (NEMS) systems comprising a MEMS or NEMS device comprising a suspended silicon structure or cantilever, wherein the suspended silicon structure or cantilever comprises a Si NW. The Si NW in these applications can comprise high-resolution shapes along the axis of the NW. Such high-resolution shapes can be created using the encoding methodology disclosed herein, and comprise shapes, profiles, gaps, gratings or combinations thereof having a resolution of about 10 nm to about 1000 nm. Similarly, thermoelectric materials comprising a Si NW comprising high-resolution shapes along the axis of the NW are also provided. Such thermoelectric materials can have NWs with high-resolution shapes comprising shapes, profiles, nanogaps, gratings or combinations thereof having a resolution of about 10 nm to about 100 nm. Further, the thermoelectric materials can have Si NWs that have a high electrical conductivity but low thermal conductivity. MEMS and NEMS devices have seen widespread application, for example as sensors, and often comprise three-dimensional, free-standing, or suspended semiconductor, dielectric, or metallic nano- and micro-structures.

In some embodiments a tunneling electrode comprising a Si NW is provided. The Si NW can comprise a nano-scale gap along the axis of the NW, wherein the nano-scale gap is about 1 nm to about 100 nm. In some aspects the gap is functionalized upon encountering a predetermined material. Such a predetermined material can be selected from the group consisting of phase change materials, polymers and molecules. The Si NW comprising a nano-scale gap can act as a resistive switch.

In some embodiments a field-effect transistor such as for use in a sensor, comprising a Si NW comprising a high-resolution channel in the axis of the Si NW, wherein the channel acts as a field-effect transistor, wherein the high-resolution channel has a resolution of about 10 nm to about 100 nm. The shape and size of the channel can be tailored to sense a desired compound or molecule.

In some embodiments a photodetector comprising a Si NW is provided. The Si NW as disclosed herein can comprise high-resolution shapes along the axis of the NW, wherein the high-resolution shapes can comprise shapes, profiles, nanogaps, gratings or combinations thereof having a resolution of about 10 nm to about 100 nm. In some aspects the photodetector can measure the change in photoconductivity upon absorption of radiation. Moreover, such a photodetector can measure the photocurrent generated in a p-n junction configuration or a metal-silicon Shottky barrier configuration. The shape and size of the high-resolution shapes control the wavelength of light absorption of the photodetector.

In some embodiments an atomic force microscopy tip comprising a Si NW is provided. The Si NW can comprise high-resolution shapes along the axis of the NW. As disclosed herein, the high-resolution shapes can comprise shapes, profiles, nanogaps, gratings or combinations thereof having a resolution of about 10 nm to about 100 nm.

### EXAMPLES

The following examples are included to further illustrate various embodiments of the presently disclosed subject matter. However, those of ordinary skill in the art should, in light of the present disclosure, appreciate that many changes can be made in the specific embodiments which are disclosed and still obtain a like or similar result without departing from the spirit and scope of the presently disclosed subject matter.

### Materials and Methods for Examples 1-9

Nanowire Growth

Silicon (Si) nanowires (NWs) were grown with a home-built, hot-wall chemical vapor deposition (CVD) system using SiH₄ (Voltaix, Branchburg, New Jersey, United States of America), PH₃ (Voltaix, LLC; diluted to 1,000 ppm in H₂), and H₂ (5N semiconductor grade; Matheson TriGas, Inc., Basking Ridge, N.J., United States of America) gases. The CVD system comprised of a quartz tube furnace (Lindberg/Blue M™) with 1 inch diameter bore, fast-responding mass-flow controllers (MKS Instruments P4B), a pressure control system (MKS Instruments 250E), and vacuum system with base pressure of 1×10⁻⁴ Torr. The CVD system was computer-controlled using custom Labview software to enable rapid and reproducible modulation of the NW growth conditions and gas flow rates. Calibration runs indicated that changes in flow rate were achieved on time scales less than 1 second and that complete exchange of gas within the quartz tube was achieved on a time scale of about 5 seconds. Thus, the resolution of Si NW morphology and structures was primarily limited by the kinetics of the NW growth or etching process and not by the mechanics of the CVD system. For a typical NW growth run, citrate-stabilized about 100 nm Au catalysts (BBI International) were dispersed on 2 cm×1 cm Si wafers (University Wafer; p-type Si with 600 nm thermal oxide) that had been functionalized with poly-L-lysine solution (Aldrich, St. Louis, Mo., United States of America). These growth substrates were inserted into the center of the tube furnace, and the furnace temperature was ramped to 450° C. to nucleate NW growth for between 5 to 60 min using 2.00 standard cubic centimerters per minute (sccm) SiH₄ and 200.0 sccm H₂ at 40.0 Torr total reactor pressure. The reactor temperature was then cooled (1° C./min) to 420° C. and Si NW structures were encoded by introducing PH₃ gas with a tightly controlled flow profile.

Etching and Device Fabrication

In some embodiments, to fabricate Si NWs with a desired morphology and/or structures, NWs were transferred from the growth substrates onto Si wafers coated with 100 nm thermal oxide and 200 nm Si nitride (Nova Electronic Materials). NWs, which were then lying flat on the substrate, were etched by immersing in concentrated buffered hydrofluoric acid (Transense BHF Improved) for 10 seconds, rinsing in water and isopropanol, etching in KOH solution (20.0 g KOH; 80.0 g water; 20 mL isopropanol as top surface layer) at 40° C. for variable times up to 90 seconds, and rinsing in water and isopropanol. To fabricate Si NWs with Noble metal structures, Si NWs were etched as described above and then placed in an electron-beam evaporator (Thermionics VE-100) for deposition of 50 nm Au at normal incidence with a rate of about 1 Å/s at a pressure less than 1×10⁻⁷ Torr. Thermal oxidation of NWs was performed for 3 min in a quartz tube furnace with 100 Torr O₂ at 1000° C. NW devices were fabricated by defining metal contacts to individual NWs using electron-beam lithography followed by electron-beam evaporation of 3 nm Ti and 150 nm Pd. Devices were measured under nitrogen environment using a home-built probe station equipped with W probe tips (Signatone) connected to a Keithley 2636A sourcemeter. Single voltage pulses were applied using a square wave pattern with nominal width of 100 μs, the minimum pulse width produced by the available measurement system. Prior to operation as a resistive switch for non-volatile memory, an electroforming process consisting of multiple voltage sweeps to high bias was performed. A typical forming process contained two sweeps from 0-30 V, two sweeps from 0-25 V and two sweeps from 0-20 V. Following the final 0-20 V sweep, additional sweeps from 0-15 V would reproducibly yield the characteristic ‘switching’ I-V behavior shown FIG. 5D.

Electron and Raman Microscopy

SEM imaging was performed with an FEI Helios 600 Nanolab Dual Beam system with an imaging resolution of less than 5 nm using a typical acceleration voltage of 5 kV and imaging current of 86 pA. Raman imaging was performed with a Renishaw inVia Raman microscope using a HeNe laser source at 633 nm and 50× objective. Spectra were collected by raster scanning the sample in steps of 100 nm using an averaging time of 1.0 s. Prior to Raman image collection, the Au-coated substrates were immersed in an aqueous solution of methylene blue (Aldrich), rinsed with water, and dried with flowing N₂. Three-dimensional plots of the Raman signal were generated by summing all counts within the 1580-1650 cm⁻¹ spectral window.

Finite-Element Simulations

Optical and device simulations were performed using the Comsol Multiphysics commercial software package. Three-dimensional optical simulations were implemented using the total-field, scattered-field method. The background field was evaluated with a plane wave normally-incident on the substrate using periodic boundary conditions on the four horizontal boundaries, a perfectly matched layer (PML) on the lower boundary, and the plane wave source on the upper boundary. The scattered field was then solved after adding the Si/Au plasmonic structure to the simulation domain and replacing all boundaries with PMLs. Images of the surface plasmon modes were generated by evaluating the scattered electric field intensity (|E|²) in a horizontal plane 3 nm above the top surface of the NW. Finite-element device simulations were performed using a modification of a previously published model (Christensen et al., 2012) and used cylindrical symmetry to represent the three-dimensional structure. The external voltage was applied to Ohmic contacts on the n-type regions, and the simulations included realistic doping profiles as well as drift-diffusion and recombination processes to reproduce the current-voltage characteristics of the devices.

### Example 1

### Synthesis of Si NWs with Desired Morphological Features

Si NWs were grown by a VLS mechanism in a home-built, hot-wall chemical vapor deposition (CVD) system at 420° C. using Au nanoparticles as catalysts, silane (SiH₄) as the source of Si, and hydrogen (H₂) as the carrier gas (see MATERIALS AND METHODS FOR EXAMPLES 1-9 for further details). As illustrated schematically in FIGS. 1A through 1C, an additional flow of phosphine (PH₃) was rapidly modulated during growth to encode varying levels of P, an n-type substitutional dopant with high solubility in Si. Since the etch rate of doped Si with aqueous KOH solution decreases with higher dopant concentration, this effect was developed as a tool to encode arbitrary and/or intentional, high-resolution morphology along the NW growth axis.

### Example 2

### Analysis and Optimization of Methods and Systems of Synthesizing Engraved Si NWs

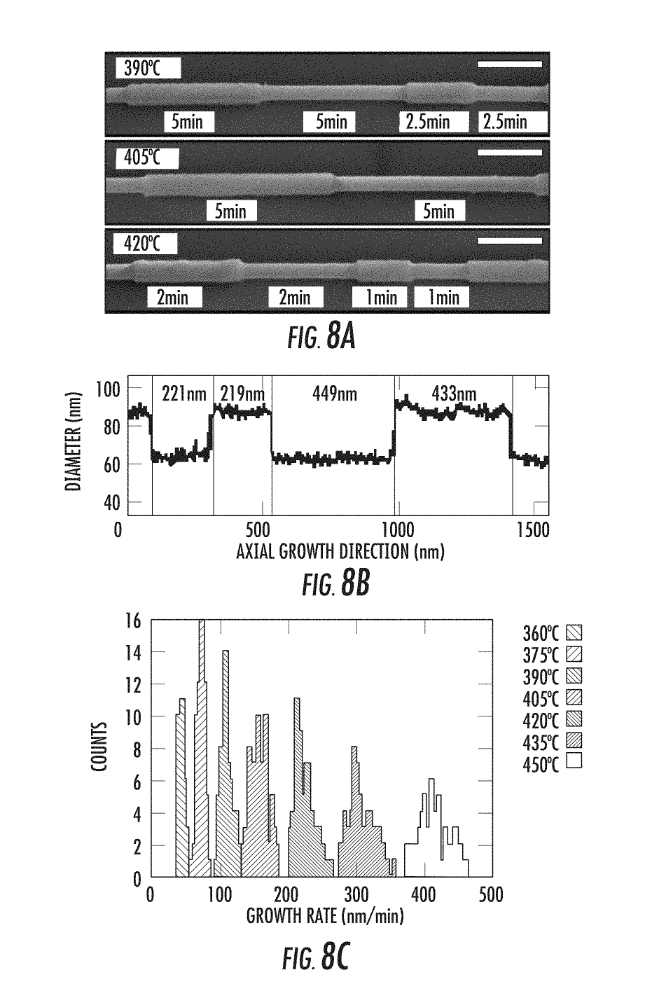

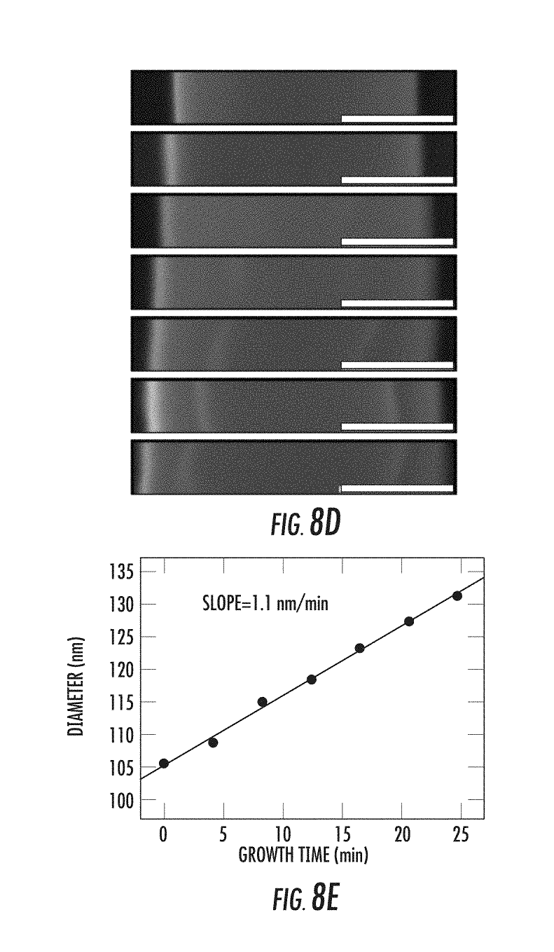

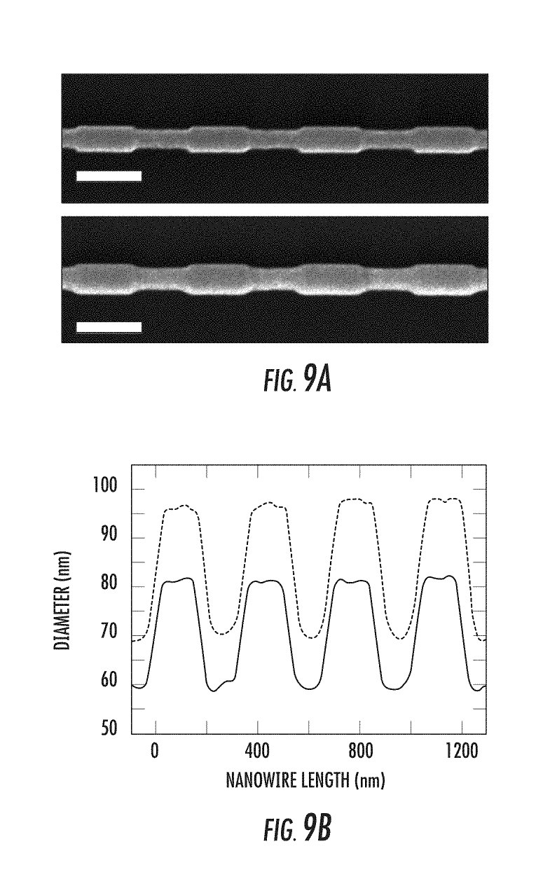

To optimize the disclosed methods and systems of synthesizing engraved Si NWs, the NW growth rate as a function of temperature was calibrated, as illustrated in FIG. 6A and detailed further in FIGS. 8A-8E. Under the disclosed CVD growth conditions, the rates follow an Arrhenius dependence on temperature, and the best fit to the measured growth rates yielded an activation energy of 22±2 kcal/mol. FIG. 8A provides an SEM images of n-type/intrinsic ‘on’/‘off’ segments formed at growth temperatures of 390° C. (top panel), 405° C. (middle panel), and 420° C. (bottom panel) and etched for 15 seconds with growth times indicated below segments (scale bars, 100 nm). FIG. 8B illustrates the diameter profile acquired from 420° C. SEM image in FIG. 8A. FIG. 8C is a histogram of measured VLS growth rates from 360° C. to 450° C. FIG. 8D provides a series of SEM images of a Si NW grown at 510° C. exhibiting significant overcoating, where images were taken in increments of 10 μm along the NW growth axis beginning just below the Au catalyst (top image; scale bars, 50 nm). And FIG. 8E is a graph plotting measured diameter as a function of growth time for the images in FIG. 8D.

Based on these findings, two important effects of growth temperature on the Si NW structures were observed. First, temperatures >430° C. produced substantial radial over-coating of the NW surface by a vapor-solid process, and this over-coating impeded consistent etching of the NWs. Measurements of the over-coating rate yielded an activation energy of 42±3 kcal/mol and an estimated rate <0.05 nm/min for temperatures below 430° C. This rate was sufficiently low to have no noticeable impact on the Si NWs even over length scales of tens of microns. For example, high-fidelity gratings as shown in FIG. 2A could be reproducibly encoded over a length scale of 50 um. Second, temperatures below 400° C. produced slow growth rates <135 nm/min and NWs that would occasionally kink, producing undesired non-linear structures. Thus, in some embodiments the optimal temperature range is likely to be about 400-430° C. In some aspects, a temperature of 420° C. with a calibrated growth rate of 213±6 nm/min has been successfully used, including for example some of the experiments disclosed herein.

### Example 3

### Delineating the Spatial Resolution of Methods of Synthesizing Si NWs

To delineate the spatial resolution of the disclosed methods of synthesizing Si NWs, NWs were synthesized with six intrinsic segments encoded along the axis for increasingly short time scales. As shown in FIG. 1C, wet-chemical etching of these segments yielded an abrupt and conformal reduction in the NW diameter. The largest segment, encoded for 200 seconds, produced a feature about 700 nm in length while the smallest segment, encoded for 5 seconds, produced a feature about 10 nm in length, defining the approximate lower limit of the spatial resolution for this process. This example also demonstrated that NW growth time is directly proportional to spatial length scale. Quantitative analysis of the NW growth rate yielded a value of 213±6 nm/min, which was used in some embodiments disclosed herein to convert growth times to length scales. This rate is comparatively slow because of the low CVD temperature, 420° C., chosen to minimize radial over-coating and doping of the NW surface. By minimizing the over-coating, high-fidelity nanoscale features could be encoded over macroscopic length scales, as exemplified in FIG. 2A which shows a 400 nm-pitch grating encoded over 50 um of a single NW.

### Example 4

Analysis of Etch Rate in the Synthesis of NWs with Complex Morphology

For the synthesis of NWs with complex morphology the etch rate was measured for Si NWs encoded with P doping levels ranging from 5.0×10²⁰ to less than 1.0×10¹⁹ dopants/cm³, as depicted in FIG. 2B. Note that these doping levels were calculated from the gas-phase ratio of Si to P during CVD growth and the actual values could be lower as a result of incomplete P incorporation. Quantitative evaluation of the etch rate revealed a non-linear dependence on doping level that is well approximated with a single exponential function and varies from 2.1 nm/s for ‘intrinsic’ segments with doping levels <1.0×10¹⁹ cm⁻³ to negligible etching (<0.1 nm/s) with heavily doped segments. Without being bound by any particular theory or mechanism of action, the exponential dependence is possibly a result of the logarithmic dependence of the Fermi level position on the doping level, which modulates the rate of Si oxidation and dissolution at the semiconductor-solution interface.

### Example 5

### Design and Synthesis of High-Resolution Morphologies in NW Synthesis

The precise calibration of the NW growth and etch rates enabled the development of rational design and synthesis of arbitrary high-resolution morphologies, as outlined schematically in FIG. 1A. This process can in some embodiments involve: 1) design of a desired morphological profile; 2) conversion of a physical profile into a dopant profile; 3) VLS growth of the dopant-encoded NW; and 4) wet-chemical etching. By way of example, this procedure was used to form the bow-tie structure depicted in FIG. 2C. The phosphine flow profile for the bow-tie (light curve in FIG. 2D) is relatively complex, requiring over 25 changes in flow rate over a time scale of one minute. The diameter profile (heavy curve in FIG. 2D) shows the resulting structure to be smoothly tapered with a monotonically decreasing then increasing diameter that reduces to a diameter of about 15 nm at the narrowest point. Note that the phosphine flow profile was modified to be asymmetric around the flow minimum to account for dopants retained by the Au catalyst, a phenomenon sometimes referred to as the reservoir effect.

### Example 6

### Analysis of Range of Complex Morphological Features in NWs

A range of doping profiles (FIGS. 3A-3J), some relatively complex, were used to encode the range of morphological features shown in SEM images in FIGS. 3A′-3J′. These structures include periodic (FIGS. 3A′-3D′) or non-periodic (FIG. 3E′) gratings, nanogaps with gap sizes as small as 10 nm (FIGS. 3F′-3G′), suspended nanorods (FIG. 3H′), and sinusoidal profiles (FIGS. 3I′ to 3J′). The exemplary morphologies illustrated in FIGS. 3A′-3J′ can in some embodiments provide for various classes of NW-based technologies. By way of example and not limitation, the suspended nanorods (FIG. 3H′) could be used as mechanical oscillators for nanoelectromechanical systems, periodic gratings (FIGS. 3A′-3D′) for optical applications in nanophotonics, and non-periodic gratings (FIG. 3E′) as a method to control thermal transport along the wires, enabling the use of Si as a thermoelectric material.

### Example 7

### Analysis of Optical Characteristics of Encoded Si NWs

Based on the disclosed robust strategy to encode complex shapes in Si NWs, efforts were next undertaken to demonstrate the potential application of these methods and systems for bottom-up nanophotonic structures with specific optical characteristics. Analysis was conducted to demonstrate that shape can in some aspects substantially influence the interaction of light with these nanostructures. For NWs with diameters in the range of about 50 nm to about 500 nm, it is known that small changes in size and shape can substantially alter absorption (Kim et al., 2012) and scattering properties (Bronstrup et al., 2010). As shown by the dark-field optical microscopy and SEM images in FIG. 7A, NWs were synthesized with diameters of 100 nm (I), 50 nm (II), and alternating 100/50 nm segments (III), which appear light, dark, and the alternating light/dark, respectively. Measurement of the scattering spectrum from NWs I and II (FIG. 7A) yield distinct spectra, and the spectrum of the modulated NW (panel III of FIG. 7A) is a weighted sum of I and II, as illustrated in FIG. 7B.

### Example 8

### Synthesis and Analysis of Si NWs with Nanoplasmonic Structures

Field-enhanced spectroscopies, such as surface-enhanced Raman spectroscopy (SERS), are often performed using Noble metal nanostructures that support surface plasmon polaritons (SPPs) (Willets et al., 2007). Through careful design of the shape of a nanostructure, SPP resonances can be used to confine and amplify incident electromagnetic fields at specific wavelengths and spatial positions (Schuller et al., 2010). Following the procedure depicted in FIG. 4A, nanogap-encoded NWs were used as the topological templates for Noble metal films, creating Si/Au nanostructures with tunable SPP resonances. As shown by the SEM images in FIGS. 4B and 4C, deposition of about 50 nm of Au on the NWs by physical vapor deposition preserved the high-resolution structures and nanogap morphology. Finite-element optical simulations (see FIGS. 4D and 4E) were used to design Si/Au Si NW structures with specific SPP characteristics. The NWs can behave as plasmonic resonator antennas, in which the length of the segments adjacent to the gap control the field enhancement as a result of constructive or destructive interference of the SPP wave along the NW axis. For a wavelength of 633 nm, segments of about 775 nm in length were found to be on-resonance, producing intense fields in the gap, while segments about 1175 nm in length were off-resonance, exhibiting weaker field enhancement.

SERS imaging was performed on the Si/Au NWs coated with methylene blue. A greater than ten-fold Raman signal enhancement was observed from the on-resonance structure, as shown by the spectra in FIG. 4F. In addition, Raman imaging (see FIGS. 4G and 4H) confirmed that the signal enhancement is localized to a narrow spatial region around the gap. In comparison, the off-resonance NW showed a weak Raman signal arising from both the gap and the two ends of the rods, a result that is in good agreement with the optical simulations in FIGS. 4D and 4E. These results highlight the capability for the disclosed methods and systems for synthesizing Si NWs to serve as a route or mechanism to create nanoplasmonic structures with tunable resonances applications such as field-enhanced spectroscopy and nanophotonic technologies.

### Example 9

### Synthesis and Analysis of Si NWs with Morphologies Imparting Electronic Characteristics

Core/shell Si/SiO₂ nanorod-encoded devices were synthesized for use as resistive switches in non-volatile memory. The fabrication steps are illustrated in FIG. 5A. An n-type/intrinsic/n-type NW was synthesized with a 50 nm intrinsic channel. The channel was etched to a diameter of about 30 nm to produce a suspended nanorod. The wire was then thermally oxidized to create an about 10 nm diameter Si core encased by an oxide shell. Thermal oxidation of etched NWs is illustrated in FIGS. 9A and 9B. In FIG. 9A SEM images of a NW grating are shown before (top panel) and after (bottom panel) thermal oxidation at 1000° C. for 10 min to form an about 15 nm thick thermal oxide layer (scale bars, 200 nm). FIG. 9B shows the diameter profile of the NW gratings in FIG. 9A before (solid line) and after (dashed line) thermal oxidation.

Electrical contacts were then fabricated to the two n-type segments adjacent to the intrinsic channel, as shown by the SEM image in FIG. 5B. Device simulations (see FIG. 5C) indicate that this geometry concentrates the voltage drop and electric field within the narrow channel region, enabling a resistive switching effect as observed in a planar Si/SiO₂ system. Initial current-voltage (I-V) measurements showed an Ohmic response from the device with a resistance of 54.7 kΩ, indicating the presence of a thin Si filament encapsulated by the SiO₂ shell. After an electroforming process consisting of multiple I-V sweeps at high bias, the device converged to the characteristic ‘switching’ I-V behavior (see FIG. 5D) expected from a Si/SiO₂ system. The I-V curve exhibits a low voltage region that ‘sets’ the device to a low resistance state and a high voltage region that ‘resets’ the device to a high resistance state. In the latter state, variations in the current were observed (see FIGS. 5D and 5E) similar to those reported previously in Si/SiO₂ resistive switching memory devices and attributed to tunneling current fluctuations (Yao et al., 2010).

To use the nanorod-encoded device as non-volatile memory, sequential ‘set’ and ‘reset’ voltage pulses (100 μs) of 8 V and 12 V, respectively, were applied to reversibly change the resistance of the device. As shown in FIG. 5E, the NW device was cycled through ten memory states and achieved on/off current ratios of nearly 10². Based on this it is expected that at least 100 memory bits could be encoded on a single NW and lower voltage operation achieved with smaller nanorod segments. These results demonstrate the facile integration of Si NW structures as provided herein in electronic devices and furthermore highlight the emergent electronic characteristics that can be encoded through morphology.

### REFERENCES

Wagner, R. S.; Ellis, W. C. Appl. Phys. Lett. 1964, 4, 89.
Benson, O. Assembly of hybrid photonic architectures from nanophotonic constituents. Nature. 480, 193-199 (2011).
Sorger, V. J., Oulton, R. F., Ma, R. M. & Zhang, X. Toward integrated plasmonic circuits. MRS Bull. 37, 728-738 (2012).
Brongersma, M. L. & Shalaev, V. M. The Case for Plasmonics. Science. 328, 440-441 (2010).
Ozbay, E. Plasmonics: Merging Photonics and Electronics at Nanoscale Dimensions. Science. 311, 189-193 (2006).
Zia, R., Schuller, J. A., Chandran, A. & Brongersma, M. L. Plasmonics: the next chip-scale technology. Mater. Today. 9, 20-27 (2006).
Barnes, W. L., Dereux, A. & Ebbesen, T. W. Surface plasmon subwavelength optics. Nature. 424, 824-830 (2003).
Schuller, J. A., Barnard, E. S., Cai, W., Jun, Y. C., White, J. S. & Brongersma, M. L. Plasmonics for extreme light concentration and manipulation. Nature Mater. 9, 193-204 (2010).
Hess, O., Pendry, J. B., Maier, S. A., Oulton, R. F., Hamm, J. M. & Tsakmakidis, K. L. Active nanoplasmonic metamaterials. Nature Mater. 11, 573-584 (2012).
de Leon, N. P., Lukin, M. D. & Park, H. Quantum Plasmonic Circuits. IEEE J. Sel. Top. Quantum Electron. 18, 1781-1791 (2012).
Beausoleil, R. G., Kuekes, P. J., Snider, G. S., Wang, S. Y. & Williams, R. S. Nanoelectronic and nanophotonic interconnect. Proc. IEEE 96, 230-247 (2008).
Halas, N. J., Lal, S., Link, S., Chang, W.-S., Natelson, D., Hafner, J. H. & Nordlander, P. A Plethora of Plasmonics from the Laboratory for Nanophotonics at Rice University. Adv. Mater. 24, 4842-4877 (2012).
Lindquist, N. C., Nagpal, P., McPeak, K. M., Norris, D. J. & Oh, S. H. Engineering metallic nanostructures for plasmonics and nanophotonics. Rep. Prog. Phys. 75, 036501 (2012).
Novotny, L. & van Hulst, N. Antennas for light. Nature Photon. 5, 83-90 (2011).
Hutter, E. & Fendler, J. H. Exploitation of localized surface plasmon resonance. Adv. Mater. 16, 1685-1706 (2004).
Seidel, H., Csepregi, L., Neuberger, A. & Baumgärtel, H. Anisotropic Etching of Crystalline Silicon in Alkaline Solutions. J. Electrochem. Soc. 137, 3612-3626 (1990).
S.-K. Kim et al., Nano Lett. 12, 4971 (2012).
G. Bronstrup et al., ACS Nano 4, 7113 (2010).
Willets, K. A.; Van Duyne, R. P., Localized surface plasmon resonance spectroscopy and sensing. In Annu. Rev. Phys. Chem., Annual Reviews: Palo Alto, 2007; Vol. 58, pp 267.
Schuller, J. A.; Barnard, E. S.; Cai, W.; Jun, Y. C.; White, J. S.; Brongersma, M. L. Nature Mater. 2010, 9, 193.
Barnard, E. S.; White, J. S.; Chandran, A.; Brongersma, M. L. Opt. Express. 2008, 16, 16529.
Pedano, M. L.; Li, S. Z.; Schatz, G. C.; Mirkin, C. A. Angew. Chem., Int. Ed. 2010, 49, 78.
Li, S. Z.; Pedano, M. L.; Chang, S. H.; Mirkin, C. A.; Schatz, G. C. Nano Lett. 2010, 10, 1722.
Christesen, J. D.; Zhang, X.; Pinion, C. W.; Celano, T. A.; Flynn, C. J.; Cahoon, J. F. Nano Lett. 2012, 12, 6024.
Yao, J.; Sun, Z.; Zhong, L.; Natelson, D.; Tour, J. M. Nano Lett. 2010, 10, 4105.

It will be understood that various details of the presently disclosed subject matter may be changed without departing from the scope of the presently disclosed subject matter. Furthermore, the foregoing description is for the purpose of illustration only, and not for the purpose of limitation.

What is claimed is:

1. A silicon nanowire comprising high-resolution shapes produced by a method of chemically encoding high-resolution shapes in silicon (Si) nanowires (NWs) during metal nanoparticle catalyzed vapor-liquid-solid (VLS) growth or vapor-solid-solid (VSS) growth, the method comprising:
growing Si NWs using VLS or VSS growth in a chemical vapor deposition system at a predetermined growth rate;
controlling in situ phosphorus or boron doping of the Si NWs during the growth of the Si NWs; and
etching the Si NWs to form high-resolution shapes along a growth axis on the Si NWs.

2. A silicon nanowire comprising high-resolution shapes, comprising:
a silicon nanowire of about 5 nm to about 500 nm diameter having a growth axis; and
a high-resolution shape, profile, nanogap, grating or combination thereof along the growth axis, wherein the high-resolution shape, profile, nanogap, grating or combination thereof has a resolution of about 10 nm to about 1,000 nm.

3. The silicon nanowire of claim 2, wherein the nanowire has a plurality of repeating shapes, profiles, nanogaps, gratings or combinations thereof, wherein the repeating shapes, profiles, nanogaps, gratings or combinations thereof are spaced apart by about 10 nm to about 10,000 nm.

4. The silicon nanowire of claim 2, wherein the nanowire has a length of up to about 50 to about 500 microns.

5. A nanophotonic or plasmonic structure for use in nanophotonics or plasmonics comprising a Si NW comprising high-resolution shapes along the axis of the NW, wherein the high-resolution shapes comprise shapes, profiles, nanogaps, gratings or combinations thereof having a resolution of about 10 nm to about 1000 nm.

6. A microelectromechanical (MEMS) or nanoelectromechanical (NEMS) system comprising a MEMS or NEMS device comprising a suspended silicon structure or cantilever, wherein the suspended silicon structure or cantilever comprises a Si NW comprising high-resolution shapes along the axis of the NW, wherein the high-resolution shapes comprise shapes, profiles, gaps, gratings or combinations thereof having a resolution of about 10 nm to about 1000 nm.

7. A thermoelectric material comprising a Si NW comprising high-resolution shapes along the axis of the NW, wherein the high-resolution shapes comprise shapes, profiles, nanogaps, gratings or combinations thereof having a resolution of about 10 nm to about 100 nm, wherein the Si NW has a high electrical conductivity but low thermal conductivity.

8. A tunneling electrode comprising a Si NW comprising a nano-scale gap along the axis of the NW, wherein the nano-scale gap is about 1 nm to about 100 nm.

9. The tunneling electrode of claim 8, wherein the gap is functionalized upon encountering a predetermined material, wherein the predetermined material is selected from the group consisting of phase change materials, polymers and molecules.

10. The tunneling electrode of claim 8, wherein the Si NW comprising a nano-scale gap acts as a resistive switch.

11. A field-effect transistor such as for use in a sensor, comprising a Si NW comprising a high-resolution channel in the axis of the Si NW, wherein the channel acts as a field-effect transistor, wherein the high-resolution channel has a resolution of about 10 nm to about 100 nm.

12. A field-effect transistor of claim 11, wherein the shape and size of the channel can be tailored to sense a desired compound or molecule.

13. A photodetector comprising a Si NW comprising high-resolution shapes along the axis of the NW, wherein the high-resolution shapes comprise shapes, profiles, nanogaps, gratings or combinations thereof having a resolution of about 10 nm to about 100 nm.

14. The photodetector of claim 13, wherein the photodetector measures the change in photoconductivity upon absorption of radiation.

15. The photodetector of claim 13, wherein the shape and size of the high-resolution shapes control the wavelength of light absorption of the photodetector.

16. An atomic force microscopy tip comprising a Si NW comprising high-resolution shapes along the axis of the NW, wherein the high-resolution shapes comprise shapes, profiles, nanogaps, gratings or combinations thereof having a resolution of about 10 nm to about 100 nm.
